(19) United States
(12) Patent Application Publication
(10) Pub. No.: US 2025/0076757 A1
(43) Pub. Date: Mar. 6, 2025

(54) TREATMENTS FOR METAL OXIDE PHOTORESIST FILMS

(71) Applicant: Tokyo Electron Limited, Tokyo (JP)

(72) Inventors: Ankur AGARWAL, Austin, TX (US); Michael CARCASI, Austin, TX (US)

(73) Assignee: Tokyo Electron Limited, Tokyo (JP)

(21) Appl. No.: 18/462,003

(22) Filed: Sep. 6, 2023

(51) Int. Cl. G03F 7/004

(52) U.S. Cl. CPC G03F 7/0044; G03F 7/0047

(57) ABSTRACT

A method for fabricating a semiconductor device with organometallic based photoresists and commercial extreme ultraviolet photolithography. The method for fabricating a semiconductor device includes applying organometallic based photoresist to a substrate and exposing the organometallic based photoresist to extreme ultraviolet photolithography. The method may include introducing an additive to the organometallic based photoresist to promote at least one of adhesion, passivation, reactivity and cross-linking of components in the organometallic based photoresist. The method may also include exposing the organometallic based photoresist to microwave radiation. The microwave radiation may couple with molecular motions, such as internal rotations, to enhance organometallic based photoresist cluster mobility or reorientations. In addition, microwave radiation may induce charge polarization and eddy currents in materials, resulting in induced electron transport and heating due to resistive losses.

### FIELD OF THE INVENTION

The present disclosure generally relates to methods of microfabrication for microelectronic devices including semiconductor devices, transistors, and integrated circuits.

### BACKGROUND

Organometallic based photoresists (herein referred to also as “MOR”) are promising candidates for commercial extreme ultraviolet (herein referred to also as “EUV”) photolithography. MORs are chemically distinct from conventional organic-based photoresist materials as they are composed of both photoactive metallic components and hydrophobic organic components. As a result, the methodology for MOR processing requires a tailored approach to successfully accomplish pitch, critical dimension (CD), and defectivity targets. Some areas of interest for furthering the efficacy of MOR photolithography include a) roughness control in linespace pattern, b) mitigating bridge formation in pillar pattern, c) sensitization to prevent missing pillars in pillar pattern, and d) defectivity dependence on delay time.

Accordingly, it is an object of the present disclosure to provide a method for MOR photolithography which improves upon these areas of interest.

### SUMMARY

The present disclosure is directed towards a method to fabricate a semiconductor device.

Aspect (1) includes a method for fabricating a semiconductor device. The method comprises providing a substrate; applying a layer of photoresist to the substrate; exposing the photoresist to a source of radiation; and developing the photoresist.

Aspect (2) includes the method of aspect (1), wherein the photoresist comprises a metal oxide photoresist.

Aspect (3) includes the method of aspect (2), wherein the metal component of the metal oxide photoresist comprises an oxide, organometallic, nanoparticle, or precursor of pure or mixed metals, selected from the group consisting of tin, hafnium, indium, gallium, zirconium, aluminum, nickel, tungsten, antimony, bismuth, germanium, cobalt, zinc, copper, chromium, iron, manganese, magnesium, silver, cadmium, lead, gold, palladium, or titanium.

Aspect (4) includes the method of aspect (2), wherein the chemical additive is incorporated into the photoresist before and or during the step of applying the layer of photoresist to the substrate.

Aspect (5) includes the method of aspect (4), wherein the chemical additive comprises a substance selected from the group consisting of short-chain alkenes, short-chain alkynes, conjugated aromatics, alcohols, acrylates, peroxides/persulfates, azo, dicarboxylate, inorganic, metal-metal linkers, ligand-ligand linkers, oxo-oxo linkers, metal-oxo linkers, electron carriers, free-radical propagators, reaction promoters, or film permeability modifiers.

Aspect (6) includes the method of aspect (4), wherein chemical additive is dissolved in a solvent prior to incorporation with the photoresist, the solvent being selected from the group consisting of alcohols, aromatics, esters, acids, bases, or neutral solvents.

Aspect (7) includes the method of aspect (4), wherein the chemical additive is incorporated into the photoresist by being co-dispensed with the photoresist as an aerosol.

Aspect (8) includes the method of aspect (4), wherein the chemical additive is incorporated into the photoresist by being present in a gaseous state while the layer of photoresist is being applied to the substrate.

Aspect (9) includes the method of aspect (2), wherein the chemical additive is incorporated into the photoresist by being introduced to the substrate before the application of the photoresist to the substrate.

Aspect (10) includes the method of aspect (9), wherein the chemical additive comprises a substance selected from the group consisting of peroxides/persulfates, multivinyl molecules, amides, sulfonyls, acrylates, carboxylates, or silicic compounds.

Aspect (11) includes the method of aspect (2), wherein the chemical additive is incorporated into the photoresist after exposing the photoresist to a source of radiation.

Aspect (12) includes the method of aspect (11), wherein the chemical additive exhibits self-assembly characteristics.

Aspect (13) includes the method of aspect (11), wherein the chemical additive exhibits selective adsorption characteristics.

Aspect (14) includes the method of aspect (2), wherein the photoresist is exposed to extreme ultraviolet wavelength radiation.

Aspect (15) includes a method for fabricating a semiconductor device. The method comprises providing a substrate; applying a layer of photoresist to the substrate; baking the layer of photoresist; exposing the photoresist to a source of extreme ultraviolet wavelength radiation; and developing the photoresist. In the method the photoresist is exposed to microwave radiation.

Aspect (16) includes the method of aspect (15), wherein the photoresist comprises a metal oxide photoresist.

Aspect (17) includes the method of aspect (16), wherein the metal component of the metal oxide photoresist comprises an oxide, organometallic, nanoparticle, or precursor of pure or mixed metals, selected from the group consisting of tin, hafnium, indium, gallium, zirconium, aluminum, nickel, tungsten, antimony, bismuth, germanium, cobalt, zinc, copper, chromium, iron, manganese, magnesium, silver, cadmium, lead, gold, palladium, or titanium.

Aspect (18) includes the method of aspect (16), wherein a secondary vapor species is incorporated into the photoresist.

Aspect (19) includes the method of aspect (18), wherein the secondary vapor species is comprised of a microwave inert or microwave transparent species.

Aspect (20) includes the method of aspect (19), wherein the microwave inert or microwave transparent species is selected from the group consisting of air, N₂, Ar, xylenes, toluene, carbon tetrachloride, chloroform, dichloromethane, 1,4-dioxane, tetrahydrofuran, chlorobenzene, triethylamine, ethyl acetate, pyridine, or methane.

Aspect (21) includes the method of aspect (18), wherein the secondary vapor species is comprised of a microwave reactive or microwave absorbing species.

Aspect (22) includes the method of aspect (21), wherein microwave reactive or microwave absorbing species is selected from the group consisting of water, CO₂, NH₃, alkanes, heterocyclic compounds, water, dimethylformide, n-methyl-2-pyrrolidone, butanol, acetonitrile, hexamethylphosphoramide, methyl ethyl ketone, nitromethane, o-dichlorobenzene, 1,2-dichloroethane, 2-methoxyethanol, acetic acid, dimethylsulfoxide, ethanol, methanol, nitrobenzene, formic acid, or ethylene glycol.

Aspect (23) includes the method of aspect (16), wherein a secondary liquid species is incorporated into the photoresist.

Aspect (24) includes the method of aspect (23), wherein the secondary liquid species comprises a microwave inert nonpolar solvent.

Aspect (25) includes the method of aspect (24), wherein the secondary liquid species comprises a microwave reactive polar solvent.

Aspect (26) includes the method of aspect (23), wherein the secondary liquid species comprises a microwave reactive unsaturated hydrocarbon.

Aspect (27) includes the method of aspect (23), wherein the secondary liquid species comprises a microwave reactive thermal radical initiator.

Aspect (28) includes the method of aspect (23), wherein the secondary liquid species further comprises a microwave absorbance enhancer.

Aspect (29) includes the method of aspect (16), wherein the photoresist is exposed to microwave radiation after the photoresist has been exposed to a source of extreme ultraviolet wavelength radiation.

Aspect (30) includes the method of aspect (16), wherein the photoresist is exposed to microwave radiation after the layer of photoresist has been applied to the substrate.

Aspect (31) includes the method of aspect (16), wherein the photoresist is exposed to microwave radiation after the photoresist has been developed.

Aspect (32) includes the method of aspect (16), wherein the frequency of the microwave radiation is modulated.

Aspect (33) includes the method of aspect (32), wherein the frequency of the microwave radiation is modulated from standard to ultra-high frequencies.

Aspect (34) includes the method of aspect (16), wherein the microwave radiation is supplied by a microwave baker apparatus.

Aspect (35) includes the method of aspect (34), wherein the microwave baker apparatus is configured to utilize an operational frequency band in excess of 2.45 GHz; operate at a power of several kilowatts; and operate under vacuum conditions and/or non-vacuum conditions.

Aspect (36) includes a method for fabricating a semiconductor device. The method comprises: applying a MOR to a substrate; exposing the MOR to EUV; developing the exposed MOR; introducing an additive to promote at least one of adhesion, passivation, reactivity and cross-linking of components in the MOR; and activating the additive.

### BRIEF DESCRIPTION OF THE DRAWINGS

Various embodiments of this disclosure that are proposed as examples will be described in detail with reference to the following figures, wherein like numerals reference like elements, and wherein:

FIG. 1A is a process flow for one preferred embodiment of the present invention.

FIG. 1B is a perspective view of a semiconductor device being manufactured according to the method of FIG. 1A.

FIG. 2A is a process flow for one preferred embodiment of the present invention.

FIG. 2B is a perspective view of a semiconductor device being manufactured according to the method of FIG. 2A.

FIG. 3A is a process flow for one preferred embodiment of the present invention.

FIG. 3B is a perspective view of a semiconductor device being manufactured according to the method of FIG. 3A.

FIG. 4A is a process flow for one preferred embodiment of the present invention.

FIG. 4B is a perspective view of a semiconductor device being manufactured according to the method of FIG. 4A.

FIG. 5 is a process flow for one preferred embodiment of the present invention.

FIG. 6 is a process flow for one preferred embodiment of the present invention.

FIG. 7 is a comparison of two graphs comparing the microwave exposure pattering of two embodiments of the present invention.

FIG. 8 is a perspective view of a semiconductor device being manufactured according to the method of a preferred embodiment of the present invention.

### DETAILED DESCRIPTION OF EMBODIMENTS

The following disclosure provides many different embodiments, or examples, for implementing different features of the provided subject matter. Specific examples of the method are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein in reference to various fabrication methods have been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Example embodiments will now be described with reference to the figures.

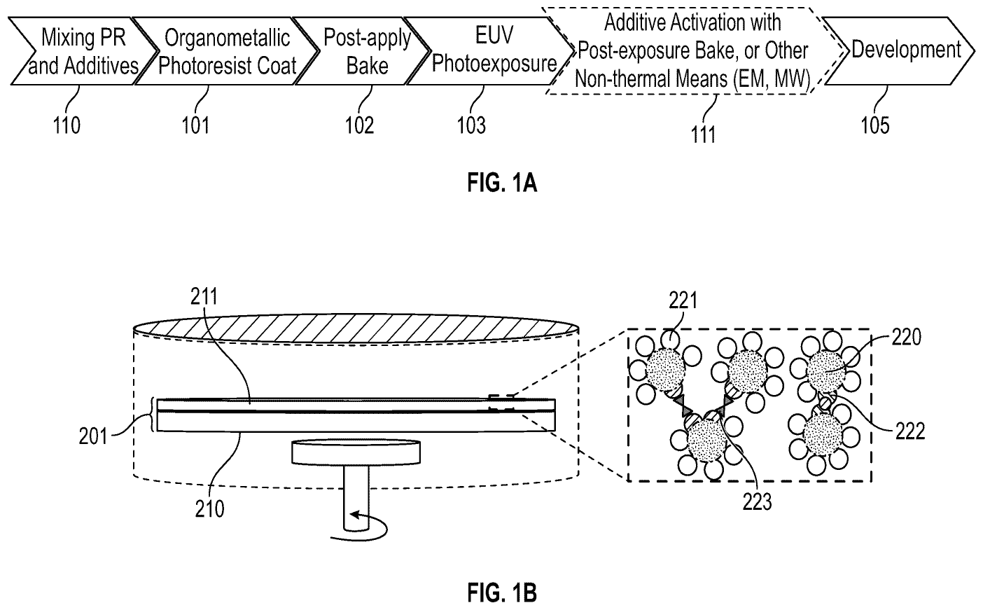

FIG. 1A illustrates a process flow for one preferred embodiment of the present invention. First, chemical additives 223 may be directly mixed with MOR 211 during a mixing step 110. The chemical additives 223 may be selected to act as one or more of following: metal-metal linkers, ligand-ligand linkers, oxo-oxo linkers, metal-oxo linkers, electron carriers, free-radical propagators, reaction promoters, and film permeability modifiers. The chemical additives 223 may be in a liquid or vapor (gaseous) phase. The introduction of liquid additives 223 may occur by methods including but not limited to: mixing of the additive 223 with the MOR 211 (such as with stir tank or three-way mixing valve etc.) before the dispense, or co-dispensing with the MOR 211 (such as with secondary dispense nozzle, atomizer nozzle, or coaxial nozzle etc.). The introduction of vapor additives 223 may occur by methods selected to prevent bubbles in the MOR 211, including but not limited to, co-dispensing as aerosol during MOR 211 dispense, or dispensing the MOR 211 in a pressure-controlled environment of vapor additives 223 supplied by a secondary line with a pump.

The chemical additives 223 may comprise short-chain alkenes (eg. ethylene) or alkynes (eg. acetylene), conjugated aromatics (eg. divinylbenzene), alcohols (eg. ethylene glycol), acrylates (eg. n-butyl acrylate), peroxides/persulfates (eg. ammonium persulfate), azo (eg. 4,4′-Azobis(4-cyanovaleric acid)), dicarboxylate (eg. terephthalic acid), inorganic compounds (eg. Iron oxide) for the purpose of complexing agents, metal-metal linkers, ligand-ligand linkers, oxo-oxo linkers, metal-oxo linkers, electron carriers, free-radical propagators, reaction promoters, and film permeability modifiers. The chemical additives 223 may be dissolved in common industrial and lithography solvents or may be converted from natively powder forms to phases suitable for application. These solvents may comprise chemicals such as alcohols (eg. isopropyl alcohol), ketones (eg. acetone), aromatics (eg. toluene), esters (eg. propylene glycol methyl ether acetate), acids (eg. aqueous acetic acid), bases (eg. TMAH), or neutral substances (eg. DI water).

Referring still to FIG. 1A, after the mixing step 110, the MOR 211 is then applied to a substrate 210, or other suitable base layer, in a coating step 101. This coating step 101 may occur simultaneously with the mixing step 110 through a co-dispense of the two materials (such as with secondary dispense nozzle, atomizer nozzle, or coaxial nozzle etc.). MOR 211 may be applied by spin-coating or any other suitable method of photoresist application. Following the coating step 101, the wafer 201 is then treated with post-application baking 102 through the introduction of heat or by non-thermal means such as exposure to electromagnetic radiation. Following post-application baking 102, the wafer 201 undergoes photoexposure 103. Preferably this photoexposure 103 is conducted using EUV techniques. The wafer 201 may then undergo a second activation step 111; wherein traditional baking techniques, or the application of electromagnetic radiation, is used to activate the chemical additive 223. The wafer 201 may then undergo traditional photolithographic development 105.

Referring now to FIG. 1B, the chemical additives 223 may comprise complexing agents which can form a network of ionic complex networks between metal particle/clusters 220. The variety of linkers function by extending the length scale of crosslinking reactions and reducing the time scale of the photolithography process, as smaller linker molecules have higher configurational and translational degrees of freedom than bulkier partially crosslinked MOR species. The chemical additives may comprise complexing agents. The chemical additives 223 may comprise carriers which function by abstracting, donating, replenishing, or distributing active sites 222 in their local neighborhood. The chemical additives 223 may comprise reaction promoters which may catalyze the reactions associated with linkers and carriers. The reactive functions of the linkers and carriers described above are only possible in the photoactivated regions of MOR that are composed of active sites 222. By comparison, the functions of linkers and carriers are chemically inactive in inactivated regions 221 of MOR due to the absence of active sites 222, therefore the functions are largely dominated by physical effects associated with thermal and diffusive behavior of molecules, thereby tuning film permeability that may affect accessibility and permeability in inactive regions 221 of MOR film by other chemicals utilized in the subsequent process steps of semiconductor device fabrication.

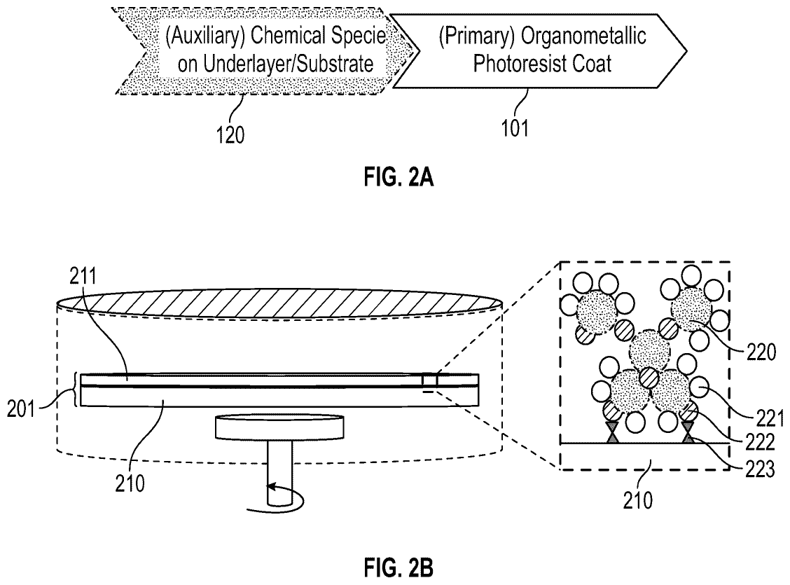

FIG. 2A illustrates a process flow for another embodiment of the present invention. In the first step of this process, chemical additives 223 are introduced via an auxiliary process fluid dispense 120 onto the substrate 210 or suitable underlayer. This auxiliary process fluid dispense 120 preferably occurs prior to the coating step 101. This introduction of liquid species may occur by methods including, but not limited to, sequential dispensing before the coating step 101 (such as with secondary dispense nozzle, atomizer nozzle, or coaxial nozzle etc.). The introduction of vapor additives 223 may occur by methods including, but not limited to, dispensing as an aerosol onto the substrate 210, or underlayer, prior to coating step 101 or the dispensing of MOR 211 in a pressure-controlled environment of vapor chemical additives supplied by a secondary line and controlled with a pump. After introduction of the chemical additives 223, the wafer 201 may undergo thermal or non-thermal stimuli to embed the additive 223 onto the top surface of the substrate 210 or the underlayer, prior to coating step 101.

Referring now to FIG. 2B, the chemical additives 223 may comprise, but are not limited to, peroxides/persulfates, multivinyl molecules, amides, sulfonyls, acrylates, carboxylates, or silicic compounds, which may generate active sites after adsorption-reaction with the underlayer/substrate surface and remain largely localized. After the coating step 101 and photoexposure 103, these underlayer active sites may react (such as with crosslinking, condensation, complexation, free radical mechanisms etc.) with active sites 222, which are present in the photoactivated region and absent in the photo-unexposed regions, thereby selectively increasing MOR particle/cluster 220 adhesion in the photoactivated regions. The selective adhesion of MOR pattern regions may improve exposure contrast during developer action.

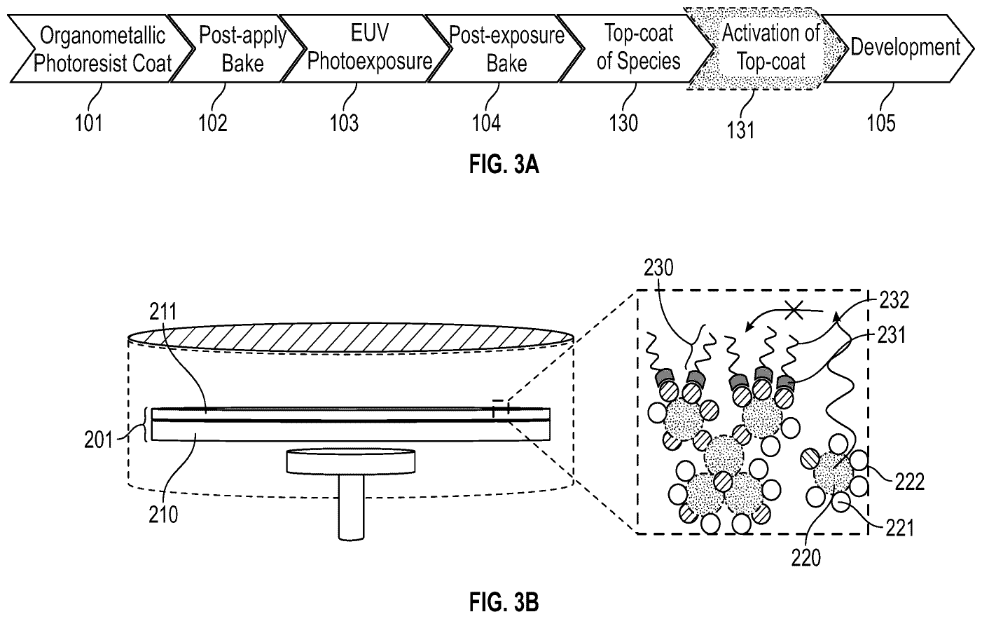

FIG. 3A illustrates a process flow for another embodiment of the present invention. Herein, MOR 211 is applied to the substrate 210; the wafer 201 undergoes post-application baking 102; the wafer 201 undergoes photoexposure103; the wafer 201 undergoes a post-exposure bake 104; and then a top-coat is applied 130 to the wafer 201. This top-coat may comprise a top-coat species 230. The Top-coat species 230 may be in a liquid phase, a vapor phase, or any combination thereof. The introduction of top-coat species 230 may occur after photoexposure 103 by methods including but not limited to, pressure-controlled introduction of top-coat species 230 supplied by a secondary line with a pump and exhaust line, aerosol dispense from a pressurized tank of modifiers, and chemical vapor deposition. The introduction of liquid top-coat species 230 may occur after photoexposure 103 by methods including but not limited to co-dispensing (such as with secondary dispense nozzle, atomizer, or coaxial nozzle etc.), which may be subject to thermal, or non-thermal stimuli, or at least one subsequent post-exposure bake 104, in process, to allow configurational reorganization, adsorption, and vaporization of excess top-coat species 230 from the surface. To obtain top-coat species 230 for the above process application, the top-coat species 230 may be combined or dissolved with secondary chemicals such as alcohols (eg. isopropyl alcohol), ketones (eg. acetone), aromatics (eg. toluene), esters (eg. propylene glycol methyl ether acetate), acids (eg. aqueous acetic acid), bases (eg. Tetramethylammonium hydroxide), or neutral chemicals (eg. DI water), with or without salts (eg. potassium chloride) depending on the nature of the modifier.

Referring now to FIG. 3B, top-coat species 230 may belong to the class of chemicals that exhibit self-assembly or selective adsorption properties, typically characterized by asymmetric long-chain molecules, or amphiphilic organic molecules, or hybrid organic-inorganic molecules, or molecules with anchoring functional head groups with hydrophilic affinity 231. Some examples of such chemicals may be silanes (eg. dodecyltrichlorosilane), siloxanes (eg. (m,p)-(Aminoethyl aminomethyl) phenethyl trimethoxysilane), thiols (eg. hexyl azobenzene thiol), phosphates (eg. dodecyl phosphate), and ionic liquids (eg. 1-butyl-3-methylimidazolium chloride). During the formation of the top-coat species 230 above photoexposed MOR 211, the top-coat species 230 adsorb preferentially with metallic or hydrophilic components in an ordered fashion and weakly with hydrophobic components such as the ligand-rich components of MOR 211. The pattern of metallic or hydrophilic regions and hydrophobic ligand-rich regions matches the exposed pattern in MOR film 211. As a result, the top-coat may selectively form a thin-layer above the photoactivated region and shield the active sites 222. During development 105, the top-coat may prevent reattachment of dissolving MOR particle/clusters 220, guide developer molecules to unexposed regions of MOR film 211, prevent contamination of the surface from environmental exposure (ions or precipitates), and/or shield the MOR film 211 from harsh developers.

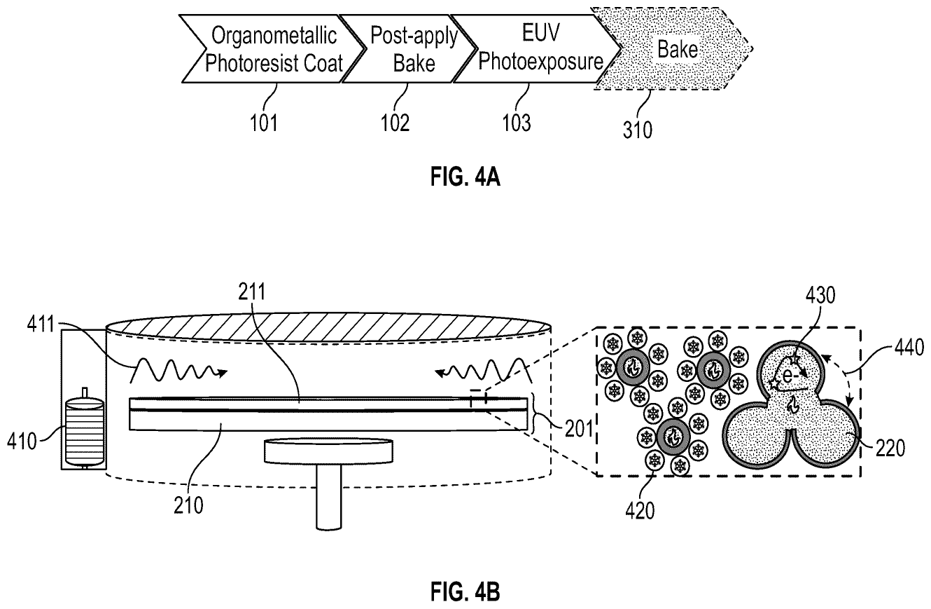

FIG. 4A illustrates a process flow for another embodiment of the present invention. Herein, the substrate 210 is coated with MOR in a coating step 101; the wafer 201 undergoes a post-application bake 102; the wafer 201 undergoes EUV photoexposure 103; and finally, the wafer 201 is exposed to microwave radiation (herein referred to also as “MW”) 310. This exposure to microwave radiation 411 may occur in a microwave baker apparatus 410. A microwave baker apparatus 410 may have an operational frequency band of 2.45 GHz or higher (wavelength; λ≤12 cm) and operate at a power of several kW. The microwave baker apparatus 410 may operate under vacuum or in a controlled environment.

Still referring to FIG. 4A, MW heating of a wafer 201 after photoexposure 103 may be an alternative to, or used in combination with, common conventional heating processes. The subsequent process steps for semiconductor device fabrication may remain unchanged. After photoexposure 103, the MOR film 211 is patterned with regions composed of MOR particle/clusters 220 (activated or crosslinked or hydroxylated) and complemented by regions of organic-rich metal-containing material depending on the photoexposure intensity across the film. The former region (R^{M}) has higher MW absorption, is composed of larger metal-oxide clusters, has a surface largely constituting the metal-oxide sites, and has a higher occupancy of active components such as hydroxyls, free radicals, secondary electrons, undercoordinated atoms, or ionized atoms relative to the latter region (R^{O}). The proposed MW heating of this wafer 201 after photoexposure 103 may result in selective absorption of longer wavelength microwaves by MOR film211 in R^{M}, which is analogous to selective absorption in hybrid materials.

Referring now to FIG. 4B, the effect of MW heating may be categorized into at least structural, thermoelectric, and thermodynamic effects. Firstly, MW may couple with molecular motions, such as internal rotations 440 to enhance MOR particle/cluster 220 mobility or reorientations in R^{M} resulting in a) increased accessibility to reactive sites for crosslinking of partially activated or hydroxylated MOR to potentially improve exposure image contrast, and b) induce cluster realignment for roughness healing of the pattern. In addition, MW may induce charge polarization and eddy currents in materials, resulting in induced electron transport 430 and heating 420 due to resistive losses. The relatively larger cluster sizes of metal-oxide in R^{M} may result in relatively larger losses (heating) 420, and longer electron transport 430 (diffusion). The former may enable higher temperature bakes of metal-oxide components with lower overall energy consumption and without thermal degradation of MW transparent components in the wafer 201, in addition to faster cycle times which may improve process yields. The latter can assist secondary charge or electron transport 430 within R^{M} to improve upon the stochastic noise from EUV photoexposure 103. Finally, the MW radiation may promote faster reaction rates through reduced reaction activation barriers in metal and metal-oxide supported catalytic systems, thereby promoting faster reactions in the reactive region of MOR 211, i.e. R^{M}, and potentially improve wafer-per-hour output and reducing defectivity originating from partially reacted MOR 211.

The MW heating of the wafer 201 may be combined with a conventional heating processes before or after the MW operation 310, including but not limited to, conductive hot-plate or convective baking, or other standard processes, for the purpose of a) establishing a uniform temperature profile across the wafer, b) heating MOR film 211 and underlayer components transparent to MW, or c) removing volatile by-products and other undesired species. In the next step, the soluble components in MOR 211, which are largely composed of [symbol] , are removed with standard lithographic processes, including but not limited to, development 105 such as a wet development with dissolving agents, to reveal the pattern. Finally, the wafer 201 may be transferred to subsequent semiconductor device fabrication processing and integration steps, including but not limited to, etch transfer, deposition, implantation, or metallization.

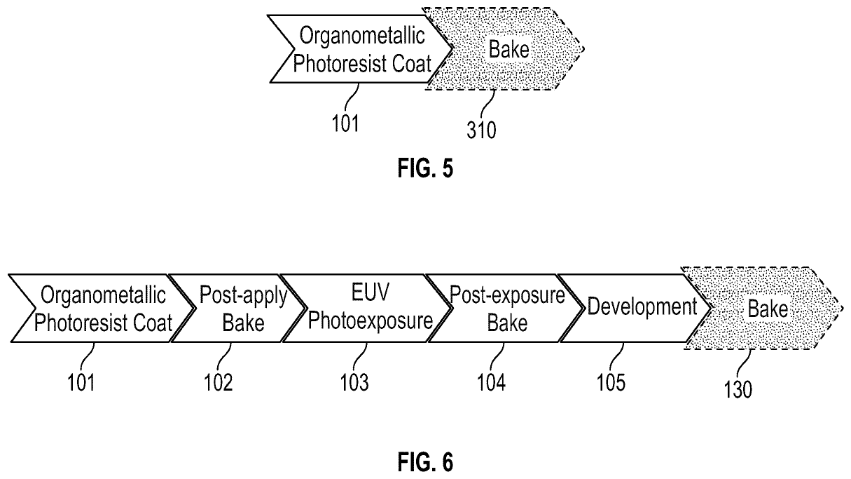

FIG. 5 illustrates a process flow for another embodiment of the present invention. Herein, after the coating step 101, the wafer 201 undergoes a MW operation 310 step. The MW heating of the wafer 201 after introduction of the MOR during a coating step 101 may occur as an alternative to, or in combination with, commonly used conventional heating processes (conductive hot-plate or convective baking), whereas the subsequent process steps for semiconductor device fabrication remain unchanged. MW may induce structural modification of the wafer 201 to enhance the absorption coefficient (and affect other optical and dielectric properties) of thin organic-inorganic films in low photon energy sources to improve desirable properties of MOR films 211 such as EUV absorption. The improved absorption coefficient may amplify the photochemical response of MOR 211 after photoexposure 103 by, amongst other processes, increasing primary and secondary electron generation, ionization, and/or dissociation.

FIG. 6 illustrates a process flow for another embodiment of the present invention. Herein, the standard steps for EUV photolithography are generally followed: MOR is applied to a substrate 210; the wafer 201 undergoes a post-application bake 102; the wafer 201 undergoes a EUV photoexposure 103; the wafer 201 undergoes a post-exposure bake 104; the wafer 201 is developed 105; and then the wafer 201 is exposed to MW radiation 411 which heats the wafer 201. MW heating of the wafer 201 after development 105 may be an alternative to, or used in combination with, common conventional heating processes (such as conductive hot-plate or convective baking), whereas the subsequent process steps for semiconductor device fabrication remain unchanged. Methods for dissolution or development 105 of patterns to reveal features in the MOR film 211, conventional heating processes (if any), and subsequent process steps are beyond the scope of this disclosure. Structural modification by MW of nanoscale MOR 211 components (like MOR fragments or MOR molecules) may affect the short-and long-range structural order of thin organic-inorganic films, which may improve feature characteristics of the ultimate product such as roughness, size, and defectivity. Improved metrology is important for downstream processing (such as etch-transfer, deposition etc.) and operation of semiconductor devices.

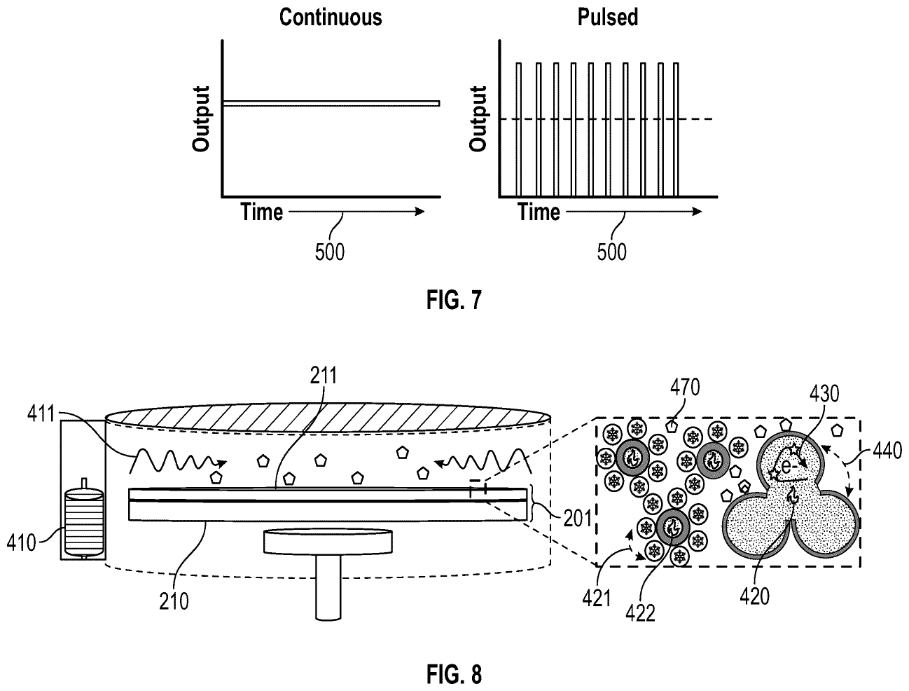

Referring now to FIG. 7, in another embodiment of the present invention, alternate modes of MW operation 310 may be implemented by frequency and power modulation of MW radiation and apparatus respectively, the latter by means of continuous 500, or pulsed 510 operations, or combinations therefore. MW operation 310 on MOR 211 containing wafers 201 may be conducted in combination with any of the above embodiments as an alternate to, or in combination with, commonly used conventional heating processes (such as conductive hot-plate or convective baking); the subsequent process steps for semiconductor device fabrication remain unchanged. MW operation 310 may facilitate condensation, isomerization, and cyclization reactions. The MW frequency used may be tuned from standard frequencies to ultra-high frequencies (≥2.45 GHz) to selectively promote desirable reaction scheme and products by resonance with normal modes of, including but not limited to, metal-ligand bond, metal-hydroxyl bond, or ion-ion pairs. In addition, the continuous 500 or pulsed 510 MW operation may present different thermal uniformity, and grain structure. Finally, the MW baker apparatus may be operated so as to vary both the frequency of the MW radiation and the frequency of operation cycle, thereby controlling both the MW energy transfer and thermal relaxation, with the selective structural, thermoelectric, and thermodynamic effects associated with specific MW frequencies.

Referring now to FIG. 8, in another embodiment of the present invention, MW operation 310 may occur in an a controlled environment, facilitated by secondary species 470, either by a) introduction of vapor species 470 in the MW baker apparatus 410 with a connected process line controlled by a standard low-pressure pump and monitored with a pressure gauge in combination with an exhaust line, or b) dispensing and spin coating liquid species on the wafer by a primary dispense line typically at the center of the wafer and transferring the wafer to the MW baker apparatus 410. This embodiment may be used in combination with existing process steps for semiconductor device fabrication or any other process described in this disclosure.

The first category of secondary vapor species 470 include but are not limited to MW inert (such as air, N₂, Ar), and MW transparent (non-polar solvent vapors: xylenes, toluene, carbon tetrachloride, choloroform, dichloromethane, 1,4-dioxane, tetrahydrofuran, chlorobenzene, triethylamine, ethyl acetate, pyridine, methane) species. These species 470 may transfer excess heat 421 from MOR films 211 or MW generated thermal hot spots to the environment and mediate structural modifications in MOR components at the photoresist's 211 surface, which may comprise a film.

The second category of secondary vapor species 470 include, but are not limited to, MW-reactive species (such as: water, CO2, NH3, alkanes, heterocyclic compounds etc.), MW-absorbing species (such as polar protic or aprotic solvents: water, dimethylformide, n-methyl-2-pyrrolidone, butanol, acetonitrile, hexamethylphosphoramide, methyl ethyl ketone, nitromethane, o-dichlorobenzene, 1,2-dichloroethane, 2-methoxyethanol, acetic acid, dimethylsulfoxide, ethanol, methanol, nitrobenzene, formic acid, ethylene glycol etc.). These species 470 may interact with MOR films 211, and transfer excess heat 421 to MOR films 211. These species 470 may also act as linkers, electron or free-radical enrichers, and/or cause passivation of excess surface active sites. The use of these species 470, especially in conjunction with MW operation 310, allows control of the reactive region to be preferentially near the MOR films 211 which may prevent undesirable reactions in other homogenous regions of the apparatus.

The secondary liquid species may comprise the similar family of chemicals as the vapor species 470 mentioned above, including but not limited to a) MW-inert non-polar solvents, b) MW-reactive polar solvents, c) MW-reactive unsaturated hydrocarbons, d) MW-reactive thermal radical initiators. The liquid species may also be combined with soluble ions, salts, metallic nanoparticles, and metallic clusters to enhance the MW absorbance of the secondary species 470. The MW operation 310 on wafers 201 with liquid species may also be performed under vacuum or with a controlled vapor environment of secondary vapor species 470. The liquid species may exhibit similar effects as the secondary vapor species 470, however they may interact not only with MOR film's surface 211, but also within the film facilitated by adsorption of liquid species within the MOR films 211. Collectively, the introduction of secondary species 470 during or before MW operation 310 may reduce defectivity, pattern roughness, and improve EUV stochastics.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

What is claimed is:

1. A method comprising:
applying an organometallic based photoresist to a substrate;
exposing the organometallic based photoresist to extreme ultraviolet radiation;
developing the exposed organometallic based photoresist; and
introducing an additive to promote at least one of adhesion, passivation, reactivity and cross-linking of components in the organometallic based photoresist.

2. The method of claim 1, wherein the organometallic based photoresist comprises an oxide, organometallic, nanoparticle, or precursor of pure or mixed metals, selected from the group consisting of tin, hafnium, indium, gallium, zirconium, aluminum, nickel, tungsten, antimony, bismuth, germanium, cobalt, zinc, copper, chromium, iron, manganese, magnesium, silver, cadmium, lead, gold, palladium, or titanium.

3. The method of claim 2, wherein the additive is incorporated into the organometallic based photoresist before and or during the step of applying the organometallic based photoresist to the substrate.

4. The method of claim 3, wherein the additive comprises a substance selected from the group consisting of short-chain alkenes, short-chain alkynes, conjugated aromatics, alcohols, acrylates, peroxides/persulfates, azo, dicarboxylate, inorganic, metal-metal linkers, ligand-ligand linkers, oxo-oxo linkers, metal-oxo linkers, electron carriers, free-radical propagators, reaction promoters, or film permeability modifiers.

5. The method of claim 3, wherein the additive is dissolved in a solvent prior to incorporation with the organometallic based photoresist, the solvent being selected from the group consisting of alcohols, aromatics, esters, acids, bases, or neutral solvents.

6. The method of claim 3, wherein the additive is incorporated into the organometallic based photoresist by being co-dispensed with the photoresist as an aerosol.

7. The method of claim 3, wherein the additive is incorporated into the organometallic based photoresist by being present in a gaseous state while the layer of organometallic based photoresist is being applied to the substrate.

8. The method of claim 1, wherein the additive is incorporated into the organometallic based photoresist by being introduced to the substrate before the application of the photoresist to the substrate.

9. The method of claim 8, wherein the additive comprises a substance selected from the group consisting of peroxides/persulfates, multivinyl molecules, amides, sulfonyls, acrylates, carboxylates, or silicic compounds.

10. The method of claim 1, wherein the additive exhibits self-assembly and/or selective adsorption characteristics, and the additive is incorporated into the organometallic based photoresist after exposing the organometallic based photoresist to a source of radiation.

11. A method comprising:
applying an organometallic based photoresist to a substrate;
baking the organometallic based photoresist;
exposing the organometallic based photoresist to extreme ultraviolet radiation; and
developing the organometallic based photoresist;
wherein, the organometallic based photoresist is exposed to microwave radiation.

12. The method of claim 11, wherein a secondary species is incorporated into the organometallic based photoresist.

13. The method of claim 12, wherein the secondary species is comprised of a microwave inert, microwave transparent, microwave reactive, or microwave absorbing species.

14. The method of claim 12, wherein the secondary species is selected from the group consisting of air, N₂, Ar, xylenes, toluene, carbon tetrachloride, chloroform, dichloromethane, 1,4-dioxane, tetrahydrofuran, chlorobenzene, triethylamine, ethyl acetate, pyridine, methane, microwave inert nonpolar solvents, microwave reactive polar solvents, microwave reactive unsaturated hydrocarbons, microwave reactive thermal radical initiators, or microwave absorbance enhancers.

15. The method of claim 11, wherein the photoresist is exposed to microwave radiation after the photoresist has been exposed to extreme ultraviolet radiation.

16. The method of claim 11, wherein the photoresist is exposed to microwave radiation after the layer of photoresist has been applied to the substrate.

17. The method of claim 11, wherein the photoresist is exposed to microwave radiation after the photoresist has been developed.

18. The method of claim 11, wherein the frequency of the microwave radiation is modulated.

19. The method of claim 11, wherein the microwave radiation is supplied by a microwave baker apparatus configured to:
utilize an operational frequency band in excess of 2.45 GHz;
operate at a power of several kilowatts; and
operate under vacuum.

20. A method comprising:
applying an organometallic based photoresist to a substrate;
exposing the organometallic based photoresist to extreme ultraviolet radiation;
developing the exposed organometallic based photoresist;
introducing an additive to promote at least one of adhesion, passivation, reactivity and cross-linking of components in the organometallic based photoresist;
wherein, the additive is activated with microwave radiation.
